(19) United States
(12) Patent Application Publication
(10) Pub. No.: US 2026/0096443 A1
(43) Pub. Date: Apr. 2, 2026

(54) CAPACITOR MOUNTING BOARD

(71) Applicant: Murata Manufacturing Co., Ltd., Nagaokakyo-shi (JP)

(72) Inventors: Ryo KASAI, Nagaokakyo-shi (JP); Yukihiro FUJITA, Nagaokakyo-shi (JP)

(21) Appl. No.: 19/272,107

(22) Filed: Jul. 17, 2025

(30) Foreign Application Priority Data
Sep. 30, 2024 (JP) 2024-170854

(51) Int. Cl. H01L 23/64; H01L 23/00; H01L 23/498; H01L 25/16

(52) U.S. Cl. CPC H10W 44/601; H10W 70/65; H10W 70/685; H10W 90/00; H10W 90/701; H10W 90/724

(57) ABSTRACT

A capacitor mounting board includes a substrate, (M×N) power lands, and (M−1)×(N−1) capacitors each in a region surrounded by (2×2) adjacent power lands. Each of the capacitors includes first and second main surfaces, first and third side surfaces, and second and fourth side surfaces. Each of the capacitors is at least on the first main surface, includes electrode terminals, has a rectangular or substantially rectangular shape at the first and second main surfaces, and is arranged such that an edge of the first capacitor main surface on the first capacitor side surface side and an edge of the first capacitor main surface on the third capacitor side surface side are inclined at about 45±5 degrees with respect to a straight line extending in a first direction on the second main surface of the substrate.

### CROSS REFERENCE TO RELATED APPLICATIONS

This application claims the benefit of priority to Japanese Patent Application No. 2024-170854 filed on Sep. 30, 2024. The entire contents of this application are hereby incorporated herein by reference.

### BACKGROUND OF THE INVENTION

### 1. Field of the Invention

The present invention relates to capacitor mounting boards.

### 2. Description of the Related Art

U.S. Patent Application Publication No. 2014/0252544 discloses a circuit board in which a capacitor is mounted. An integrated circuit (IC) is mounted on the first main surface side on the circuit board, and the circuit board is mounted on a motherboard on the second main surface side with a ball grid array (BGA) interposed therebetween. In the circuit board, the capacitor is mounted as a decoupling capacitor for the power supply of the IC. To be specific, on the second main surface side of the circuit board, the capacitor is disposed instead of some conductor bumps of the BGA. Thus, it is possible to dispose the decoupling capacitor in close proximity to the IC, and it is possible to improve the decoupling effect (high-frequency voltage-fluctuation reduction effect) on the power supply of the IC.

Japanese Unexamined Patent Application Publication No. 2009-130314 discloses a stacked multiterminal capacitor as an example of such a capacitor.

However, when some conductor bumps of a power BGA of a circuit board are removed in order to dispose a capacitor in close proximity to an IC, a current that flows through the remaining power conductor bumps increases, and disconnection due to electrochemical migration or the like may occur.

### SUMMARY OF THE INVENTION

Example embodiments of the present invention provide capacitor mounting boards that each enable a capacitor to be located in close proximity to an IC without removing some conductor bumps of a power BGA.

A capacitor mounting board according to an example embodiment of the present invention includes a substrate including a first substrate main surface on which an integrated circuit (IC) is to be mounted and a second substrate main surface on which a power ball grid array (BGA) to connect with a motherboard is provided, (M×N) power lands for the power BGA on the second substrate main surface of the substrate two-dimensionally in a first direction and a second direction that intersect each other, where M and N are integers greater than or equal to 2, and (M−1)×(N−1) capacitors on the second substrate main surface of the substrate each in a region surrounded by (2×2) power lands, among the (M×N) power lands, are adjacent to each other in the first direction and the second direction. Each of the (M−1)×(N−1) capacitors includes a first capacitor main surface facing the second substrate main surface of the substrate, a second capacitor main surface facing away from the first capacitor main surface, a first capacitor side surface and a third capacitor side surface facing away from each other, and a second capacitor side surface and a fourth capacitor side surface facing away from each other, includes a plurality of electrode terminals on at least the first capacitor main surface and connected to the second substrate main surface of the substrate, has a rectangular or substantially rectangular shape at the first capacitor main surface and the second capacitor main surface, and are arranged such that an edge of the first capacitor main surface on the first capacitor side surface side and an edge of the first capacitor main surface on the third capacitor side surface side are inclined at about 45±5 degrees with respect to a straight line extending in the first direction on the second substrate main surface of the substrate.

A capacitor mounting board according to another example embodiment of the present invention includes a substrate including a first substrate main surface on which an integrated circuit (IC) is to be mounted and a second substrate main surface on which a power ball grid array (BGA) to connect with a motherboard is provided, (M×N) power lands for the power BGA on the second substrate main surface of the substrate two-dimensionally in a first direction and a second direction that intersect each other, where M and N are integers greater than or equal to 2, and (M−1)×(N−1) capacitors, as seen from the second substrate main surface of the substrate, each in a region surrounded by (2×2) power lands, among the (M×N) power lands, are adjacent to each other in the first direction and the second direction. The substrate includes a core layer and two buildup layers respectively provided on the first substrate main surface side and the second substrate main surface side of the core layer and each of which includes a power wiring layer. Each of the (M−1)×(N−1) capacitors is embedded in the core layer of the substrate, includes a first capacitor main surface facing the buildup layer on the first substrate main surface side of the substrate, a second capacitor main surface facing away from the first capacitor main surface, a first capacitor side surface and a third capacitor side surface facing away from each other, and a second capacitor side surface and a fourth capacitor side surface facing away from each other, includes a plurality of electrode terminals on at least the first capacitor main surface and connected to the power wiring layer of the buildup layer on the first substrate main surface side of the substrate, has a rectangular or substantially rectangular shape at the first capacitor main surface and the second capacitor main surface, and located such that an edge of the first capacitor main surface on the first capacitor side surface side and an edge of the first capacitor main surface on the third capacitor side surface side are inclined at about 45±5 degrees with respect to a straight line extending in the first direction on the second substrate main surface of the substrate.

With example embodiments of the present invention, it is possible to provide, in capacitor mounting boards, capacitors in close proximity to ICs without removing some conductor bumps of power BGAs.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic sectional view of a capacitor mounting board according to a first example embodiment of the present invention taken along line I-I in FIG. 2.

FIG. 2 is a schematic back-side view of the capacitor mounting board according to the first example embodiment of the present invention taken along line II-II in FIG. 1.

FIG. 3 is a schematic sectional view illustrating the internal structure of a substrate of the capacitor mounting board according to the first example embodiment of the present invention taken along line III-III in FIG. 4.

FIG. 4 is a schematic back-side view of the substrate of the capacitor mounting board according to the first example embodiment of the present invention taken along line IV-IV in FIG. 3.

FIG. 5 is a schematic back-side view of a substrate of a capacitor mounting board according to a second example embodiment of the present invention taken along a line corresponding to line IV-IV in FIG. 3.

FIG. 6 is a schematic front-side view of a capacitor of the capacitor mounting board according to the second example embodiment of the present invention.

FIG. 7 is a schematic front-side view of a capacitor of the capacitor mounting board according to the second example embodiment of the present invention.

FIG. 8 is a schematic sectional view illustrating the internal structure of a substrate of a capacitor mounting board according to a third example embodiment of the present invention taken along a line corresponding to line III-III in FIG. 4.

FIG. 9 is a schematic sectional view illustrating the internal structure of a substrate of a capacitor mounting board according to a fourth example embodiment of the present invention taken along line IX-IX in FIGS. 11 to 13.

FIG. 10 is a schematic sectional view illustrating the internal structure of the substrate of the capacitor mounting board according to the fourth example embodiment of the present invention taken along line X-X in FIGS. 11 to 13.

FIG. 11 is a schematic back-side view of the substrate of the capacitor mounting board according to the fourth example embodiment of the present invention taken along line XI-XI in FIGS. 9 and 10.

FIG. 12 is a schematic back-side view of the substrate of the capacitor mounting board according to the fourth example embodiment of the present invention taken along line XII-XII in FIGS. 9 and 10.

FIG. 13 is a schematic back-side view of the substrate of the capacitor mounting board according to the fourth example embodiment of the present invention taken along line XIII-XIII in FIGS. 9 and 10.

FIG. 14 is a schematic sectional view illustrating the internal structure of the substrate of the capacitor mounting board according to the fourth example embodiment of the present invention taken along line X-X in FIGS. 11 to 13.

### DETAILED DESCRIPTION OF THE EXAMPLE EMBODIMENTS

Hereafter, example embodiments of the present invention will be described with reference to the drawings. In the drawings, the same or corresponding portions are denoted by the same numerals.

### First Example Embodiment

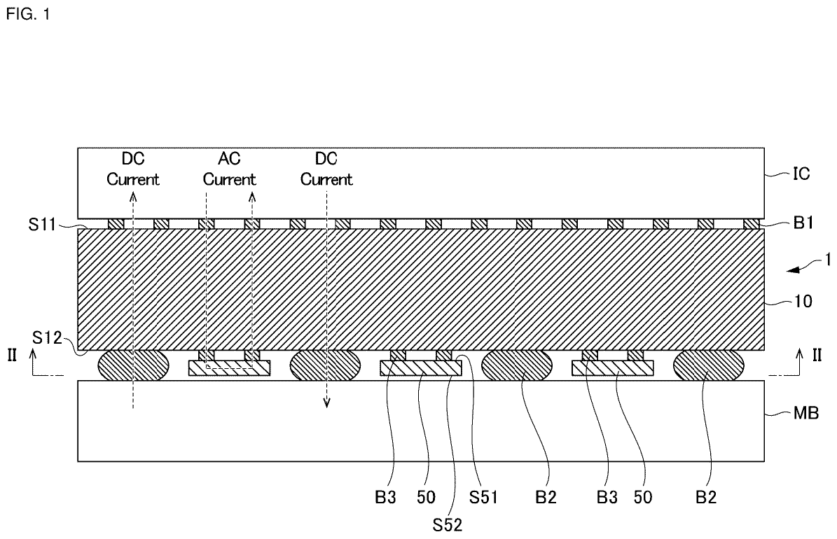

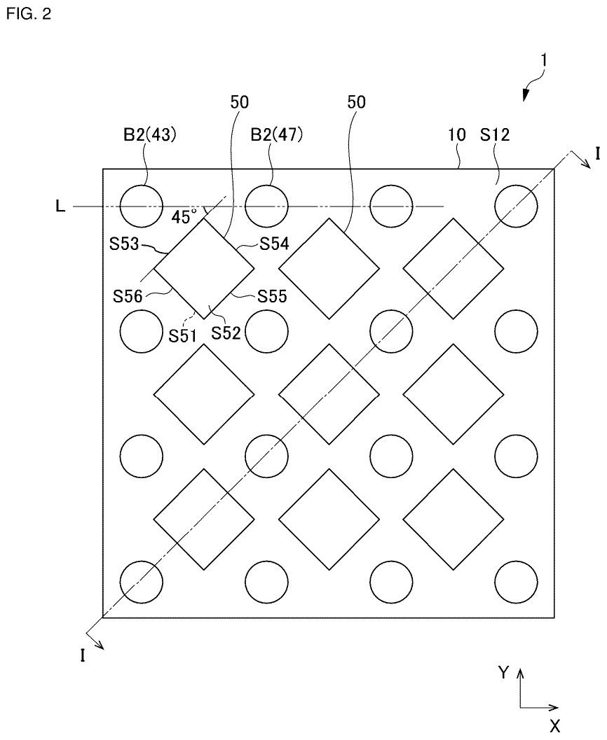

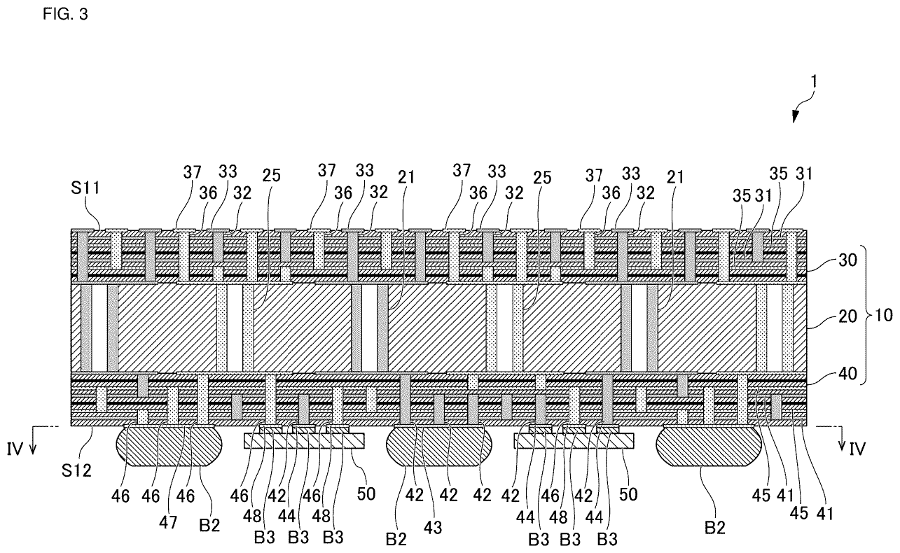

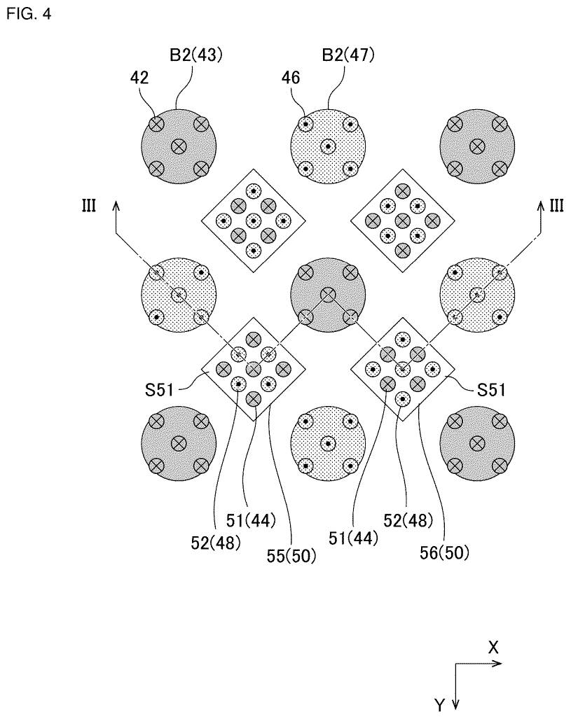

FIG. 1 is a schematic sectional view of a capacitor mounting board 1 according to a first example embodiment of the present invention taken along line I-I in FIG. 2. FIG. 2 is a schematic back-side view of the capacitor mounting board 1 according to the first example embodiment taken along line II-II in FIG. 1. FIG. 3 is a schematic sectional view illustrating the internal structure of a substrate 10 of the capacitor mounting board 1 according to the first example embodiment taken along line III-III in FIG. 4. FIG. 4 is a schematic back-side view of the substrate 10 of the capacitor mounting board 1 according to the first example embodiment taken along line IV-IV in FIG. 3.

In FIGS. 1 to 4 and other figures described below, power supply lines (VDD, GND) are illustrated, while illustrations of signal lines are omitted. Hereafter, power supply lines (VDD, GND) will be described, while description of signal lines will be omitted.

The capacitor mounting board 1 illustrated in FIGS. 1 and 2 is a package board used in an IC package. The capacitor mounting board 1 includes the substrate 10 and a plurality of capacitors 50.

On a first main surface S11 of the substrate 10, that is, on the first main surface S11 of the capacitor mounting board 1, an IC such as, for example, a processor is mounted with conductor bumps B1 interposed therebetween. The IC package is mounted on a motherboard MB with a power BGA interposed therebetween. Thus, on a second main surface S12 of the substrate 10, that is, on the second main surface S12 of the capacitor mounting board 1, a power BGA, that is, the power conductor bumps B2, to connect with the motherboard MB is disposed.

Thus, as indicated by arrows in FIG. 1, a direct current supplied from a voltage regulator is supplied to the IC through the motherboard MB, the power BGA (the power conductor bumps B2), the capacitor mounting board 1, and the conductor bumps B1. An alternating current for the power supply of the IC flows to the capacitors 50 through the conductor bumps B1 and the capacitor mounting board 1, and the high-frequency voltage fluctuation and the high-frequency noise of the power supply of the IC are reduced.

As illustrated in FIG. 3, the substrate 10 includes a core layer 20 and two buildup layers 30 and 40.

In the core layer 20, a plurality of through-holes that extend through the core layer 20 from the first main surface S1 side to the second main surface S2 side, to be specific, first-potential (for example, VDD) through-holes 21 and second-potential (for example, GND) through-holes 25 are disposed.

The buildup layer 30 is disposed on the first main surface S1 side of the core layer 20. The buildup layer 30 includes pairs of wiring layers, to be specific, two or more pairs of wiring layers each including a first-potential (for example, VDD) wiring layer 31 and a second-potential (for example, GND) wiring layer 35. The buildup layer 30 includes a plurality of conductor vias, to be specific, a plurality of first-potential (for example, VDD) conductor vias 32 and a plurality of second-potential (for example, GND) conductor vias 36. On the first main surface S11 of the buildup layer 30, a plurality of power lands (power pads), to be specific, a plurality of first-potential (for example, VDD) lands 33 and a plurality of second-potential (for example, GND) lands 37 are disposed.

The first-potential conductor vias 32 include conductor vias that are stacked from the first-potential land 33 to each of the two or more first-potential wiring layers 31 and conductor vias that are stacked from the first-potential land 33 to the first-potential through-hole 21. The second-potential conductor vias 36 include conductor vias that are stacked from the second-potential land 37 to each of the two or more second-potential wiring layers 35 and conductor vias that are stacked from the second-potential land 37 to the second-potential through-hole 25.

Thus, the first-potential land 33, the first-potential wiring layers 31 in the two or more pairs of wiring layers, and the first-potential through-hole 21 are electrically connected by the first-potential conductor vias 32. The second-potential land 37, the second-potential wiring layers 35 in the two or more pairs of wiring layers, and the second-potential through-hole 25 are electrically connected by the second-potential conductor vias 36.

Because the first-potential conductor vias 32 include conductor vias that are stacked from the first-potential land 33 to the first-potential through-hole 21 and the second-potential conductor vias 36 include conductor vias that are stacked from the second-potential land 37 to the second-potential through-hole 25, it is possible to minimize the length of the DC path, and it is possible to minimize the resistance of the DC path.

The buildup layer 40 is disposed on the second main surface S2 side of the core layer 20. The buildup layer 40 includes pairs of wiring layers, to be specific, two or more pairs of wiring layers each including a first-potential (for example, VDD) wiring layer 41 and a second-potential (for example, GND) wiring layer 45. Moreover, the buildup layer 40 includes a plurality of conductor vias, to be specific, a plurality of first-potential (for example, VDD) conductor vias 42 and a plurality of second-potential (for example, GND) conductor vias 46. On the second main surface S12 of the buildup layer 40, a plurality of power lands (power pads), to be specific, a plurality of first-potential (for example, VDD) lands 43 and a plurality of second-potential (for example, GND) lands 47 are disposed.

The first-potential conductor vias 42 include conductor vias that are stacked from the first-potential land 43 to each of the two or more first-potential wiring layers 41 and conductor vias that are stacked from the first-potential land 43 to the first-potential through-hole 21. The second-potential conductor vias 46 include conductor vias that are stacked from the second-potential land 47 to each of the two or more second-potential wiring layers 45 and conductor vias that are stacked from the second-potential land 47 to the second-potential through-hole 25.

Thus, the first-potential land 43, the first-potential wiring layers 41 in the two or more pairs of wiring layers, and the first-potential through-hole 21 are electrically connected by the first-potential conductor vias 42. The second-potential land 47, the second-potential wiring layers 45 in the two or more pairs of wiring layers, and the second-potential through-hole 25 are electrically connected by the second-potential conductor vias 46.

Because the first-potential conductor vias 42 include conductor vias that are stacked from the first-potential land 43 to the first-potential through-hole 21 and the second-potential conductor vias 46 include conductor vias that are stacked from the second-potential land 47 to the second-potential through-hole 25, it is possible to minimize the length of the DC path, and it is possible to minimize the resistance of the DC path.

On the second main surface S12 of the buildup layer 40, a plurality of capacitor lands, to be specific, a plurality of first-potential (for example, VDD) lands 44 and a plurality of second-potential (for example, GND) lands 48 are disposed.

The first-potential conductor vias 42 include conductor vias that are stacked from the first-potential land 44 to each of the two or more first-potential wiring layers 41 and conductor vias that are stacked from the first-potential land 44 to the first-potential through-hole 21. The second-potential conductor vias 46 include conductor vias that are stacked from the second-potential land 48 to each of the two or more second-potential wiring layers 45 and conductor vias that are stacked from the second-potential land 48 to the second-potential through-hole 25.

Thus, the first-potential land 44, the first-potential wiring layers 41 in the two or more pairs of wiring layers, and the first-potential through-hole 21 are electrically connected by the first-potential conductor vias 42. The second-potential land 48, the second-potential wiring layers 45 in the two or more pairs of wiring layers, and the second-potential through-hole 25 are electrically connected by the second-potential conductor vias 46.

Because the first-potential conductor vias 42 include conductor vias that are stacked from the first-potential land 44 to the first-potential through-hole 21 and the second-potential conductor vias 46 include conductor vias that are stacked from the second-potential land 48 to the second-potential through-hole 25, it is possible to minimize the length of the alternating current path including the capacitor 50, and it is possible to reduce the equivalent series inductance (ESL). Moreover, it is possible to maximize the mutual inductance between the alternating current paths.

Examples of the material of the core layer 20 include known materials such as glass epoxy, and examples of the material of the buildup layers 30 and 40 include known materials such as epoxy resin. Examples of the material of the power lands 33, 37, 43, and 47, the capacitor lands 44 and 48, the wiring layers 31, 35, 41, and 45, the conductor vias 32, 36, 42, and 46, and the through-holes 21 and 25 include known materials such as Cu.

As illustrated in FIG. 2, (M×N) power lands (power pads) 43 and 47 for the power BGA are disposed on the second main surface S12 of the substrate 10. The (M×N) power lands 43 and 47 are disposed at regular intervals (for example, about 1 mm intervals) on the second main surface S12 of the substrate 10 two-dimensionally in the first direction X and the second direction Y, which intersect each other. Here, M and N are integers greater than or equal to 2.

As described above, the (M×N) power lands 43 and 47 include the first-potential (for example, VDD) lands 43 and the second-potential (for example, GND) lands 47. The first-potential lands 43 and the second-potential lands 47 are alternately disposed in the first direction X and the second direction Y.

(M−1)×(N−1) capacitors 50 are disposed on the second main surface S12 of the substrate 10. The (M−1)×(N−1) capacitors 50 are disposed on the second main surface S12 of the substrate 10 each in a region surrounded by (2×2) power lands 43 and 47, among the (M×N) power lands 43 and 47, that are adjacent to each other in the first direction X and the second direction Y.

Each of the capacitors 50 is, for example, a multiterminal capacitor including two or more terminals, and preferably, four or more terminals. As illustrated in FIGS. 1 and 2, each of the capacitors 50 includes a first main surface S51 that faces the second main surface S12 of the substrate 10, a second main surface S52 that faces away from the first main surface S51, a first side surface S53 and a third side surface S55 that face away from each other, and a second side surface S54 and a fourth side surface S56 that face away from each other.

On at least the first main surface S51 of each of the capacitors 50, a plurality of electrode terminals, to be specific, first electrode terminals (for example, VDD) 51 and second electrode terminals (for example, GND) 52 are disposed. Each of the first electrode terminals 51 is connected to the first-potential land 44 on the second main surface S12 of the substrate 10 with a conductor bump B3 interposed therebetween. Each of the second electrode terminals 52 is connected to the second-potential land 48 on the second main surface S12 of the substrate 10 with a conductor bump B3 interposed therebetween (see FIG. 3).

On the other hand, the first electrode terminals 51 and the second electrode terminals 52 are not disposed on the first side surface S53, the second side surface S54, the third side surface S55, and the fourth side surface S56 of the capacitor 50. Thus, it is possible to reduce or prevent a short circuit between an electrode terminal of the capacitor 50 and a power conductor bump B2 due to spreading of the BGA, that is, the adjacent power conductor bumps B2.

Each of the capacitors 50 has a rectangular or substantially rectangular shape, preferably, a square or substantially square shape at the first main surface S51 and the second main surface S52. Each of the capacitors 50 is disposed such that the center of the first main surface S51 is positioned at the center of a region surrounded by (2×2) power lands that are adjacent to each other. Each of the capacitors 50 is disposed such that an edge of the first main surface S51 on the first side surface S53 side and an edge of the first main surface S51 on the third side surface S55 side are inclined at, for example, about 45±5 degrees, and preferably, about 45 degrees with respect to a straight line L extending in the first direction X on the second main surface S12 of the substrate 10.

Examples of the capacitor 50 include known Si capacitors and stacked capacitors (see, for example, Japanese Unexamined Patent Application Publication No. 2009-130314).

As illustrated in FIG. 4, the capacitors 50 include first capacitors 55 and second capacitors 56. The first capacitors 55 and the second capacitors 56 are alternately disposed in the first direction X and the second direction Y. The first capacitor 55 and the second capacitor 56 differ in the assignment (allotment and arrangement) of the first potential (VDD) and the second potential (GND). For example, in the first capacitor 55, the number of the first electrode terminals 51 is greater than the number of the second electrode terminals 52. In the second capacitors 56, the number of the first electrode terminals 51 is less than the number of the second electrode terminals 52. The total number of the electrode terminals 51 and 52 of the first capacitor 55 is the same as the total number of the electrode terminals 51 and 52 of the second capacitors 56.

Thus, it is possible to reduce or prevent the imbalance between the number of electrode terminals for the first potential (VDD) and the number of electrode terminals for the second potential (GND), and it is possible to reduce the impedance of the alternating current path including the capacitor 50.

As described above, in the capacitor mounting board 1 according to the first example embodiment, the capacitors 50 are disposed on the back surface of the substrate 10 opposite from the surface on which the IC is mounted. Thus, it is possible to dispose a decoupling capacitor in close proximity to the IC, and it is possible to improve the decoupling effect (high-frequency voltage-fluctuation reduction effect) and the high-frequency-noise reduction effect on the power supply of the IC. To be more specific, it is possible to minimize the length of a high-frequency current (alternating current) loop including the capacitor 50, it is possible to reduce the impedance of the high-frequency current (alternating current) loop, and it is possible to reduce high-frequency voltage fluctuation and high-frequency noise of the power supply of the IC.

Moreover, in the capacitor mounting board 1 according to the first example embodiment, the capacitor 50 is disposed so as to be inclined, for example, by about 45 degrees in a region surrounded by (2×2) power lands 43 and 47, among the (M×N) power lands 43 and 47, that are adjacent to each other. Thus, it is possible to dispose the capacitor 50 in close proximity to the IC without removing some conductor bumps B2 of the power BGA. Therefore, it is possible to avoid disconnection at the power conductor bump B2 due to electrochemical migration or the like, which may occur when some power conductor bumps B2 of the power BGA are removed and the current that flows through the remaining power conductor bumps B2 increases.

In the first example embodiment described above, an underfill may be interposed between the capacitor 50 and the substrate 10, to be more specific, between the first main surface S51 of the capacitor 50 and the second main surface S12 of the substrate 10. Examples of an underfill include materials such as epoxy resin.

When an underfill is interposed between the capacitor 50 and the substrate 10 in this way, it is possible to further reduce or prevent a short circuit between an electrode terminal of the capacitor 50 and a power conductor bump B2 due to spreading of the BGA, that is, the adjacent power conductor bumps B2. Moreover, with the adhesion of the underfill, it is possible to increase the bonding strength between the capacitor 50 and the substrate 10.

### Second Example Embodiment

A capacitor mounting board 1 according to a second example embodiment of the present invention differs from the capacitor mounting board 1 according to the first example embodiment in the configuration of the capacitors 50.

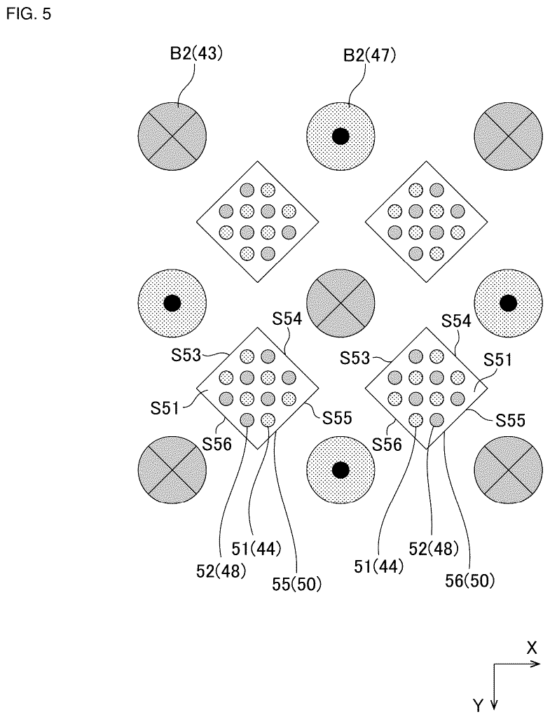

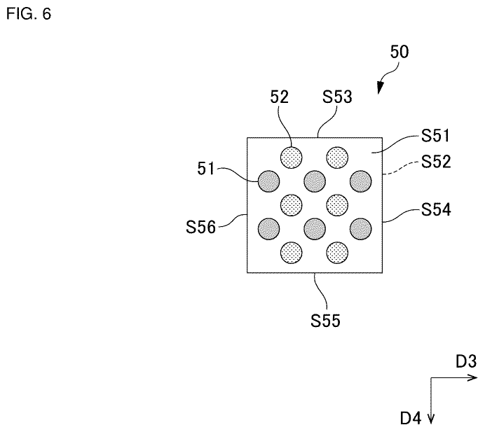

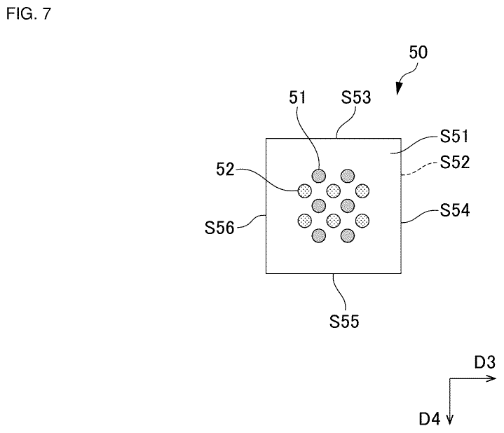

FIG. 5 is a schematic back-side view of a substrate 10 of the capacitor mounting board 1 according to the second example embodiment taken along a line corresponding to line IV-IV in FIG. 3, FIGS. 6 and 7 are each a schematic front-side view of a capacitor 50 of the capacitor mounting board 1 according to the second example embodiment.

As illustrated in FIGS. 5 and 6, the electrode terminals 51 and 52 are disposed on the first main surface S51 of the capacitor 50 in a staggered pattern. To be specific, in the capacitor 50, when a third direction D3 is defined as the direction in which the first side surface S53 and the third side surface S55 extend and a fourth direction D4 is defined as the direction in which the second side surface S54 and the fourth side surface S56 extend, electrode terminals of the same potential are arranged in the third direction D3 and an odd number of electrode terminals of different potentials are alternately arranged in the fourth direction D4. When one pitch is defined as the distance between the electrode terminals that are adjacent to each other in the third direction D3, the electrode terminals of different potentials that are adjacent to each other in the fourth direction D4 are displaced by about a half pitch in the third direction D3.

As illustrated in FIG. 5, in the capacitor 50, the power assignment of an electrode terminal, among the electrode terminals, that is nearest to the first side surface S53 is the same as the power assignment of a conductor bump, of the BGA, that is adjacent to the first side surface S53. The power assignment of an electrode terminal that is nearest to the second side surface S54 is the same as the power assignment of a conductor bump, of the BGA, that is adjacent to the second side surface S54. The power assignment of an electrode terminal, among the electrode terminals, that is nearest to the third side surface S55 is the same as the power assignment of a conductor bump, of the BGA, that is adjacent to the third side surface S55. The power assignment of an electrode terminal, among the electrode terminals, that is nearest to the fourth side surface S56 is the same as the power assignment of a conductor bump, of the BGA, that is adjacent to the fourth side surface S56. Here, the power assignment (allotment) includes a first potential (for example, VDD) and a second potential (for example, GND).

Also with the capacitor mounting board 1 according to the second example embodiment, it is possible to obtain advantageous effects the same as or similar to those of the capacitor mounting board 1 according to the first example embodiment.

In the capacitor mounting board 1 according to the second example embodiment, in the capacitor 50, the power assignment of an electrode terminal, among the electrode terminals, that is nearest to a side surface is the same as the power assignment of a conductor bump of the BGA that is adjacent to the side surface. Thus, it is possible to further reduce or prevent a short circuit between an electrode terminal of the capacitor 50 and a power conductor bump B2 due to spreading of the BGA, that is, the adjacent power conductor bumps B2.

As illustrated in FIG. 7, in the second example embodiment described above, the electrode terminals 51 and 52 may be made closer to the center of the capacitor 50, that is, the electrode terminals 51 and 52 may be disposed farther inward in the capacitor 50. To be specific, in the capacitor 50, an electrode terminal, among the electrode terminals, that is nearest to the first side surface S53 is disposed to be spaced away by a predetermined distance from (an end of) a conductor bump, of the BGA, that is adjacent to the first side surface S53. An electrode terminal, among the electrode terminals, that is nearest to the second side surface S54 is disposed to be spaced away by a predetermined distance from (an end of) a conductor bump, of the BGA, that is adjacent to the second side surface S54. An electrode terminal, among the electrode terminals, that is nearest to the third side surface S55 is disposed to be spaced away by a predetermined distance from (an end of) a conductor bump, of the BGA, that is adjacent to the third side surface S55. An electrode terminal, among the electrode terminals, that is nearest to the fourth side surface S56 is disposed to be spaced away by a predetermined distance from (an end of) a conductor bump, of the BGA, that is adjacent to the fourth side surface S56.

The predetermined distance is, for example, greater than or equal to about 170 μm when the BGA pitch is about 1 mm and the diameter of a conductor bump of the BGA is about 500 μm.

In this case, it is possible to further reduce or prevent a short circuit between an electrode terminal of the capacitor 50 and a power conductor bump B2 due to spreading of the BGA, that is, the adjacent power conductor bumps B2.

### Third Example Embodiment

A capacitor mounting board 1 according to a third example embodiment of the present invention differs from the capacitor mounting board 1 according to the first example embodiment in the positions where the capacitors 50 are disposed.

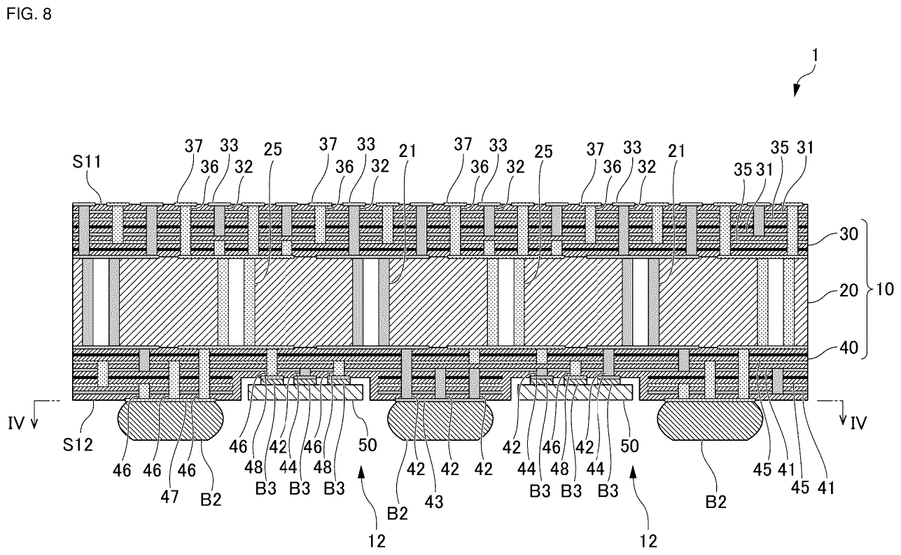

FIG. 8 is a schematic sectional view illustrating the internal structure of a substrate 10 of the capacitor mounting board 1 according to the third example embodiment taken along a line corresponding to line III-III in FIG. 4.

As illustrated in FIG. 8, the substrate 10 may include, in the second main surface S12, (M−1)×(N−1) recesses 12 each of which is disposed in a region surrounded by (2×2) power lands 43 and 47, among the (M×N) power lands 43 and 47, that are adjacent to each other in the first direction X and the second direction Y. The (M−1)×(N−1) capacitors 50 are respectively embedded in the (M−1)×(N−1) recesses 12.

In the buildup layer 40 on the second main surface S12 of the substrate 10, each of the (M−1)×(N−1) recesses 12 extends to some of the plurality of pairs of first-potential wiring layers 41 and second-potential wiring layers 45 and does not extend to at least one pair among the plurality of pairs of first-potential wiring layers 41 and second-potential wiring layers 45. That is, the recesses 12 are provided in the buildup layer 40 such that at least one of the pairs of first-potential wiring layers 41 and second-potential wiring layers 45 remains. Thus, in the buildup layer 40, it is possible to provide a conduction path in the first direction X and the second direction Y.

With the capacitor mounting board 1 according to the third example embodiment, it is possible to obtain advantageous effects the same as or similar to those of the capacitor mounting board 1 according to the first example embodiment.

In the capacitor mounting board 1 according to the third example embodiment, the capacitors 50 are embedded in the recesses 12 in the second main surface S12 of the substrate 10. Thus, it is possible to further reduce or prevent a short circuit between an electrode terminal of the capacitor 50 and a power conductor bump B2 due to spreading of the BGA, that is, the adjacent power conductor bumps B2. Moreover, it is possible to minimize the length of a high-frequency current (alternating current) loop including the capacitor 50, it is possible to reduce the impedance of the high-frequency current (alternating current) loop, and it is possible to reduce high-frequency voltage fluctuation and high-frequency noise of the power supply of the IC.

In the third example embodiment described above, the recess 12 in which the capacitor 50 is embedded may be filled with a molding material. Examples of the molding material include materials such as epoxy resin.

By filling the recess 12, in which the capacitor 50 is embedded, with a molding material in this way, it is possible to further reduce or prevent a short circuit between an electrode terminal of the capacitor 50 and a power conductor bump B2 due to spreading of the BGA, that is, the adjacent power conductor bumps B2. Moreover, with the adhesion of the molding material, it is possible to increase the bonding strength between the capacitor 50 and the substrate 10.

The entirety or substantially the entirety of the capacitor 50 may be embedded in the recess 12. In this case, because the entirety or substantially the entirety of the capacitor 50 is covered by the molding material, it is possible to further reduce or prevent a short circuit between an electrode terminal of the capacitor 50 and a power conductor bump B2.

### Fourth Example Embodiment

A capacitor mounting board 1 according to a fourth example embodiment of the present invention differs from the capacitor mounting board 1 according to the first example embodiment in the positions where the capacitors 50 are disposed.

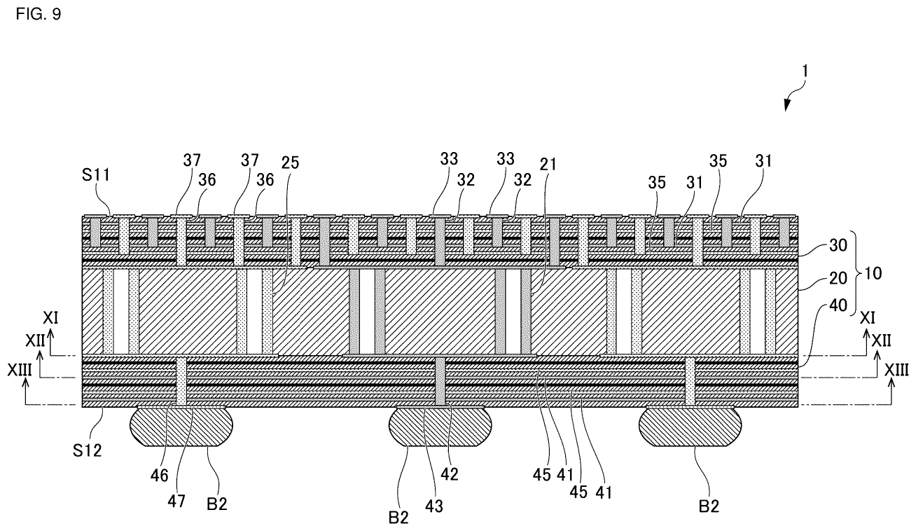

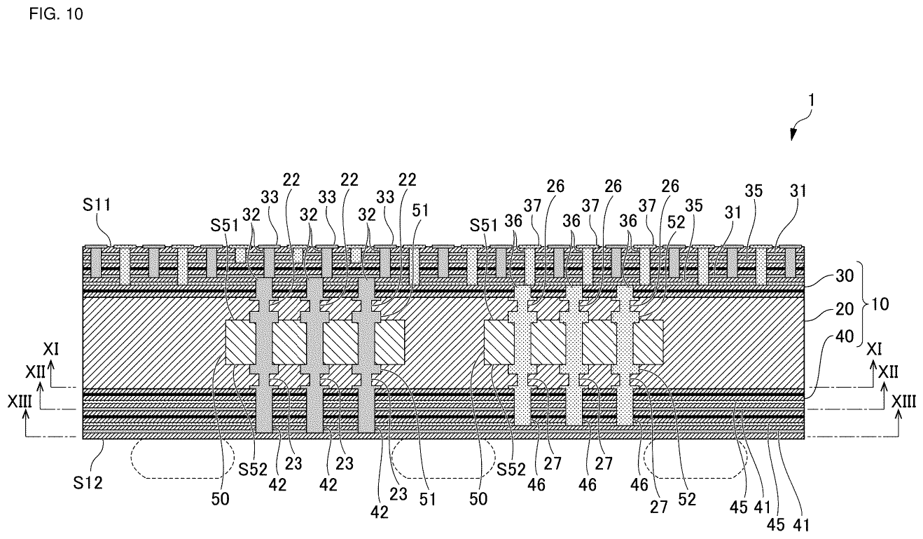

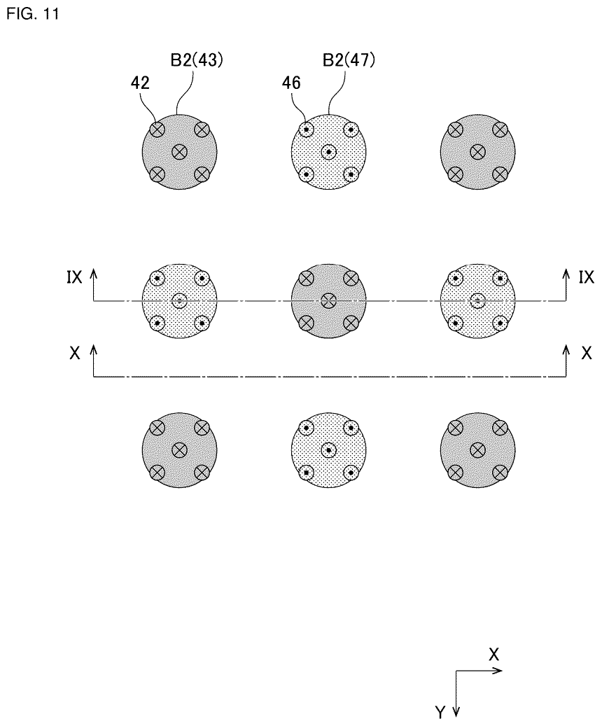

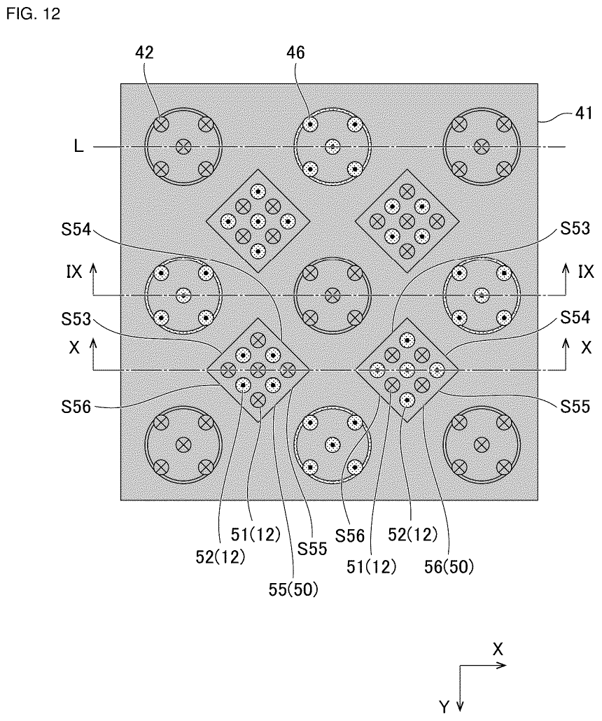

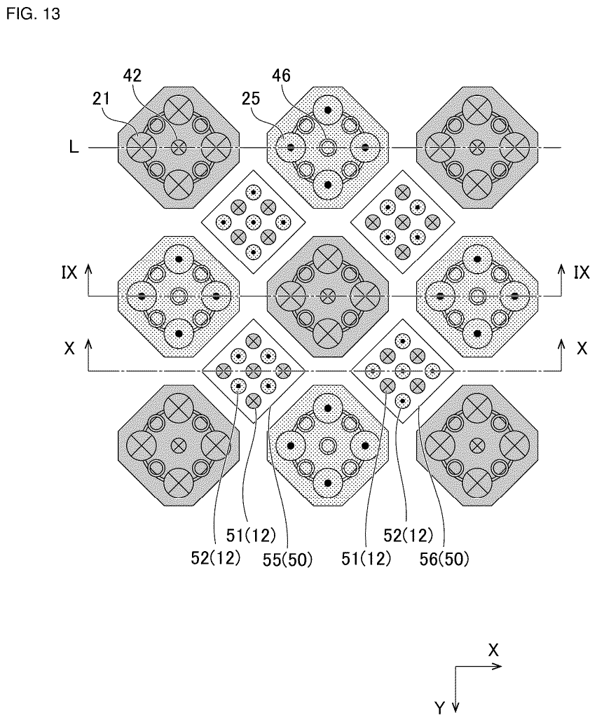

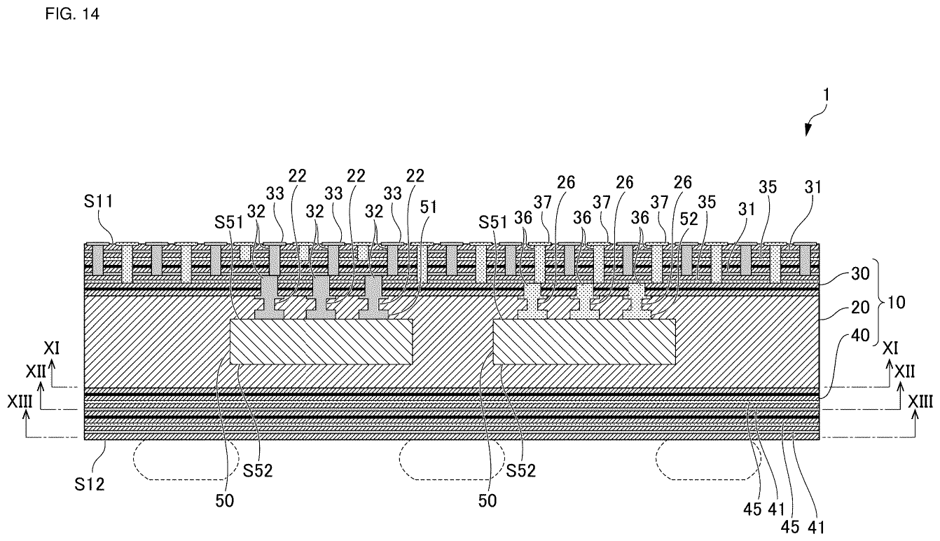

FIG. 9 is a schematic sectional view illustrating the internal structure of a substrate 10 of the capacitor mounting board 1 according to the fourth example embodiment taken along line IX-IX in FIGS. 11 to 13. FIGS. 10 and 14 are schematic sectional view each illustrating the internal structure of the substrate 10 of the capacitor mounting board 1 according to the fourth example embodiment taken along line X-X in FIGS. 11 to 13. FIG. 11 is a schematic back-side view of the substrate 10 of the capacitor mounting board 1 according to the fourth example embodiment taken along line XI-XI in FIGS. 9 and 10. FIG. 12 is a schematic back-side view of the substrate 10 of the capacitor mounting board 1 according to the fourth example embodiment taken along line XII-XII in FIGS. 9 and 10. FIG. 13 is a schematic back-side view of the substrate 10 of the capacitor mounting board 1 according to the fourth example embodiment taken along line XIII-XIII in FIGS. 9 and 10.

As illustrated in FIG. 9, also in the fourth example embodiment, in the core layer 20 of the substrate 10, a plurality of through-holes that extend through the core layer 20 from the first main surface S1 side to the second main surface S2 side, to be specific, the first-potential (for example, VDD) through-holes 21 and the second potential (for example, GND) through-holes 25 are disposed.

As illustrated in FIG. 10, the core layer 20 includes a plurality of first-potential conductor vias 22 that extend from the first electrode terminal 51 on the first main surface S51 of each of the (M−1)×(N−1) capacitors 50 to the buildup layer 30 on the first main surface S11 side of the core layer 20. Moreover, the core layer 20 includes a plurality of second-potential conductor vias 26 that extend from the second electrode terminal 52 on the first main surface S51 of each of the (M−1)×(N−1) capacitors 50 to the buildup layer 30 on the first main surface S11 side of the core layer 20.

Thus, it is possible to minimize the length of the alternating current path including the capacitor 50, and it is possible to reduce the equivalent series inductance (ESL).

The core layer 20 includes a plurality of first-potential conductor vias 23 that extend from the first electrode terminal 51 on the second main surface S52 of each of the (M−1)×(N−1) capacitors 50 to the buildup layer 40 on the second main surface S12 side of the core layer 20. Moreover, the core layer 20 includes a plurality of second-potential conductor vias 27 that extend from the second electrode terminal 52 on the second main surface S52 of each of the (M−1)×(N−1) capacitors 50 to the buildup layer 40 on the second main surface S52 side the core layer 20.

A through-via extends through the capacitor 50 from the first electrode terminal 51 on the first main surface S51 to the first electrode terminal 51 on the second main surface S52, and a through-via extends through the capacitor 50 from the second electrode terminal 52 on the first main surface S51 to the second electrode terminal 52 on the second main surface S52.

Thus, a DC path is provided by the first-potential conductor vias 42 and 23, the through-via in capacitor 50, the first-potential conductor vias 22 and 32, the second-potential conductor vias 46 and 27, the through-via in the capacitor 50, and the second-potential conductor vias 26 and 36. Thus, it is possible to reduce the impedance of the DC path.

Also in the fourth example embodiment, the buildup layer 30 of the substrate 10 includes pairs of wiring layers, to be specific, two or more pairs of wiring layers each including the first potential (for example, VDD) wiring layer 31 and the second potential (for example, GND) wiring layer 35. The buildup layer 30 includes a plurality of conductor vias, to be specific, the plurality of first-potential (for example, VDD) conductor vias 32 and the plurality of second-potential (for example, GND) conductor vias 36. On the first main surface S11 of the buildup layer 30, a plurality of power lands (power pads), to be specific, the plurality of first-potential (for example, VDD) lands 33 and the plurality of second-potential (for example, GND) lands 37 are disposed.

The first-potential conductor vias 32 include conductor vias that are stacked from the first-potential land 33 to each of the two or more first-potential wiring layers 31, and conductor vias that are stacked from the first-potential land 33 to the first-potential through-hole 21. The second-potential conductor vias 36 include conductor vias that are stacked from the second-potential land 37 to each of the two or more second-potential wiring layers 35, and conductor vias that are stacked from the second-potential land 37 to the second-potential through-hole 25.

Thus, the first-potential land 33, the first-potential wiring layers 31 in the two or more pairs of wiring layers, and the first-potential through-hole 21 are electrically connected by the first-potential conductor vias 32. The second-potential land 37, the second-potential wiring layers 35 in the two or more pairs of wiring layers, and the second-potential through-hole 25 are electrically connected by the second-potential conductor vias 36.

Because the first-potential conductor vias 32 include conductor vias that are stacked from the first-potential land 33 to the first-potential through-hole 21 and the second-potential conductor vias 36 include conductor vias that are stacked from the second-potential land 37 to the second-potential through-hole 25, it is possible to minimize the length of the DC path, and it is possible to minimize the resistance of the DC path.

The buildup layer 30 includes the plurality of first-potential conductor vias 32 that connect the first-potential wiring layers 31 in the two or more pairs of wiring layers and each of the plurality of first-potential conductor vias 22 in the core layer 20. Moreover, the buildup layer 30 includes the plurality of second-potential conductor vias 36 that connect the second-potential wiring layers 35 in the two or more pairs of wiring layers and each of the plurality of second-potential conductor vias 26 in the core layer 20.

Thus, the first electrode terminal 51 on the first main surface S51 side of the capacitor 50 and the first-potential wiring layer 31 of the buildup layer 30 are electrically connected by the first-potential conductor vias 22 of the core layer 20 and the first-potential conductor vias 32 of the buildup layer 30. The second electrode terminal 52 on the first main surface S51 side of the capacitor 50 and the second-potential wiring layer 35 of the buildup layer 30 are electrically connected by the second-potential conductor vias 26 of the core layer 20 and the second-potential conductor vias 36 of the buildup layer 30.

Also in the fourth example embodiment, the buildup layer 40 of the substrate 10 includes pairs of wiring layers, to be specific, two or more pairs of wiring layers each including a first-potential (for example, VDD) wiring layer 41 and a second-potential (for example, GND) wiring layer 45. Moreover, the buildup layer 40 includes a plurality of conductor vias, to be specific, the plurality of first-potential (for example, VDD) conductor vias 42 and the plurality of second-potential (for example, GND) conductor vias 46. On the second main surface S12 of the buildup layer 40, a plurality of power lands (power pads), to be specific, the plurality of first-potential (for example, VDD) lands 43 and the plurality of second-potential (for example, GND) lands 47 are disposed.

The first-potential conductor vias 42 include conductor vias that are stacked from the first-potential land 43 to each of the two or more first-potential wiring layers 41 and conductor vias that are stacked from the first-potential land 43 to the first-potential through-hole 21. The second-potential conductor vias 46 include conductor vias that are stacked from the second-potential land 47 to each of the two or more second-potential wiring layers 45 and conductor vias that are stacked from the second-potential land 47 to the second-potential through-hole 25.

Thus, the first-potential land 43, the first-potential wiring layers 41 in the two or more pairs of wiring layers, and the first-potential through-hole 21 are electrically connected by the first-potential conductor vias 42. The second-potential land 47, the second-potential wiring layers 45 in the two or more pairs of wiring layers, and the second-potential through-hole 25 are electrically connected by the second-potential conductor vias 46.

Because the first-potential conductor vias 42 include conductor vias that are stacked from the first-potential land 43 to the first-potential through-hole 21 and the second-potential conductor vias 46 include conductor vias that are stacked from the second-potential land 47 to the second-potential through-hole 25, it is possible to minimize the length of the DC path, and it is possible to minimize the resistance of the DC path.

The buildup layer 40 includes the plurality of first-potential conductor vias 42 that connect the first-potential wiring layers 41 in the two or more pairs of wiring layers and each of the plurality of first-potential conductor vias 23 in the core layer 20. Moreover, the buildup layer 40 includes the plurality of second-potential conductor vias 46 that connect the second-potential wiring layers 45 in the two or more pairs of wiring layers and each of the plurality of second-potential conductor vias 27 in the core layer 20.

The first-potential conductor vias 42 include conductor vias that are stacked from the first-potential conductor via 23 in the core layer 20 to the first-potential wiring layer 41 nearest to the second main surface S12. Moreover, the second-potential conductor vias 46 include conductor vias that are stacked from the second-potential conductor via 27 in the core layer 20 to the second-potential wiring layer 45 nearest to the second main surface S12.

Thus, the first electrode terminal 51 on the second main surface S52 side of the capacitor 50 and the first-potential wiring layer 41 of the buildup layer 40 are electrically connected by the first-potential conductor vias 23 of the core layer 20 and the first-potential conductor vias 42 of the buildup layer 40. The second electrode terminal 52 on the second main surface S52 side of the capacitor 50 and the second-potential wiring layer 45 of the buildup layer 40 are electrically connected by the second-potential conductor vias 27 of the core layer 20 and the second-potential conductor vias 46 of the buildup layer 40.

Because the first-potential conductor vias 42 include conductor vias that are stacked from the first-potential conductor via 23 in the core layer 20 to the first-potential wiring layer 41 nearest to the second main surface S12 and the second-potential conductor vias 46 include conductor vias that are stacked from the second-potential conductor via 27 in the core layer 20 to the second-potential wiring layer 45 nearest to the second main surface S12, it is possible to minimize the length of the alternating current path including the capacitor 50, and it is possible to reduce the equivalent series inductance (ESL). Moreover, it is possible to maximize the mutual inductance between the alternating current paths.

In the fourth example embodiment, the (M−1)×(N−1) capacitors 50 are embedded in the core layer 20 of the substrate 10. The (M−1)×(N−1)capacitors 50 are disposed, as seen from the second main surface S12 of the substrate 10, each in a region surrounded by (2×2) power lands 43 and 47, among the (M×N) power lands 43 and 47, that are adjacent to each other in the first direction X and the second direction Y.

The first main surface S51 of the capacitor 50 faces the buildup layer 30 on the first main surface S11 side of the substrate 10, and the second main surface S52 of the capacitor 50 faces the buildup layer 40 on the second main surface S12 side of the substrate 10.

On the first main surface S51 of the capacitor 50, a plurality of electrode terminals, to be specific, the first electrode terminals (for example, VDD) 51 and the second electrode terminals (for example, GND) 52 are disposed. Each of the first electrode terminals 51 on the first main surface S51 is connected, through the first-potential conductor via 22 of the core layer 20, to the first-potential conductor via 32 and the first-potential wiring layer 31 of the buildup layer 30. Each of the second electrode terminals 52 on the first main surface S51 is connected, through the second-potential conductor via 26 of the core layer 20, to the second-potential conductor via 36 and the second-potential wiring layer 35 of the buildup layer 30 (see FIG. 10).

Also on the second main surface S52 of the capacitor 50, a plurality of electrode terminals, to be specific, the first electrode terminals (for example, VDD) 51 and the second electrode terminals (for example, GND) 52 are disposed. Each of the first electrode terminals 51 on the second main surface S52 is connected, through the first-potential conductor via 23 of the core layer 20, to the first-potential conductor via 42 and the first-potential wiring layer 41 of the buildup layer 40. Each of the second electrode terminals 52 on the second main surface S52 is connected, through the second-potential conductor via 27 of the core layer 20, to the second-potential conductor via 46 and the second-potential wiring layer 45 of the buildup layer 40 (see FIG. 10).

Also in the fourth example embodiment, each of the capacitors 50 has a rectangular or substantially rectangular shape, preferably, a square or substantially square shape at the first main surface S51 and the second main surface S52. Each of the capacitors 50 is disposed such that the center of the first main surface S51 is positioned at the center of a region surrounded by (2×2) power lands that are adjacent to each other. Each of the capacitors 50 is disposed such that an edge of the first main surface S51 on the first side surface S53 side and an edge of the first main surface S51 on the third side surface S55 side are inclined at, for example, about 45±5 degrees, and preferably, about 45 degrees with respect to a straight line L extending in the first direction X on the second main surface S12 of the substrate 10.

The capacitors 50 include the first capacitors 55 and the second capacitors 56. The first capacitors 55 and the second capacitors 56 are alternately disposed in the first direction X and the second direction Y. The first capacitor 55 and the second capacitor 56 differ in the assignment (allotment and arrangement) of the first potential (VDD) and the second potential (GND). For example, in the first capacitor 55, the number of the first electrode terminals 51 is greater than the number of the second electrode terminals 52. In the second capacitors 56, the number of the first electrode terminals 51 is less than the number of the second electrode terminals 52. The total number of the electrode terminals 51 and 52 of the first capacitor 55 is the same as the total number of the electrode terminals 51 and 52 of the second capacitors 56.

Thus, it is possible to reduce or prevent the imbalance between the number of electrode terminals for the first potential (VDD) and the number of electrode terminals for the second potential (GND), and it is possible to reduce the impedance of the alternating current path including the capacitor 50.

The capacitor mounting board 1 according to the fourth example embodiment has advantageous effects the same as or similar to those of the capacitor mounting board 1 according to the first example embodiment.

As illustrated in FIG. 14, in the capacitor mounting board 1 according to the fourth example embodiment, the capacitor 50 need not include the electrode terminals 51 and 52 on the second main surface S52. In this case, the core layer 20 does not include the conductor vias 23 and 27.

Heretofore, example embodiments of the present invention have been described. However, the present invention is not limited to the example embodiments described above, and can be changed or modified in various ways.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A capacitor mounting board comprising:
a substrate including a first substrate main surface on which an integrated circuit (IC) is to be mounted and a second substrate main surface on which a power ball grid array (BGA) to connect with a motherboard is provided;
(M×N) power lands for the power BGA on the second substrate main surface of the substrate two-dimensionally in a first direction and a second direction that intersect each other, where M and N are integers greater than or equal to 2; and
(M−1)×(N−1)capacitors on the second substrate main surface of the substrate each in a region surrounded by (2×2) power lands, among the (M×N) power lands, that are adjacent to each other in the first direction and the second direction; wherein
each of the (M−1)×(N−1)capacitors:
includes a first capacitor main surface facing the second substrate main surface of the substrate, a second capacitor main surface facing away from the first capacitor main surface, a first capacitor side surface and a third capacitor side surface facing from each other, and a second capacitor side surface and a fourth capacitor side surface facing away from each other;
includes a plurality of electrode terminals on at least the first capacitor main surface and connected to the second substrate main surface of the substrate;
has a rectangular or substantially rectangular shape at the first capacitor main surface and the second capacitor main surface; and
is arranged such that an edge of the first capacitor main surface on the first capacitor side surface side and an edge of the first capacitor main surface on the third capacitor side surface side are inclined at about 45±5 degrees with respect to a straight line extending in the first direction on the second substrate main surface of the substrate.

2. The capacitor mounting board according to claim 1, wherein
the (M×N) power lands are located at regular intervals on the second substrate main surface of the substrate two-dimensionally in the first direction and the second direction; and
each of the (M−1)×(N−1)capacitors:
has a square or substantially square shape at the first capacitor main surface and the second capacitor main surface;
is arranged such that the edge of the first capacitor main surface on the first capacitor side surface side and the edge of the first capacitor main surface on the third capacitor side surface side are inclined at about 45 degrees with respect to the straight line extending in the first direction on the second substrate main surface of the substrate; and
is arranged such that a center of the first capacitor main surface is positioned at a center of the region surrounded by the (2×2) power lands that are adjacent to each other.

3. The capacitor mounting board according to claim 1, wherein, in each of the (M−1)×(N−1)capacitors, the plurality of electrode terminals are not provided on the first capacitor side surface, the second capacitor side surface, the third capacitor side surface, and the fourth capacitor side surface.

4. The capacitor mounting board according to claim 1, wherein
the (M×N) power lands include first-potential lands and second-potential lands alternately provided in the first direction and the second direction;
a number of the plurality of electrode terminals on the first capacitor main surface of each of the (M−1)×(N−1) capacitors is greater than or equal to 4; and
the plurality of electrode terminals include first electrode terminals for a first potential and second electrode terminals for a second potential.

5. The capacitor mounting board according to claim 4, wherein
the (M−1)×(N−1)capacitors include a first capacitor in which a number of the first electrode terminals is greater than a number of the second electrode terminals and a second capacitor in which the number of the first electrode terminals is less than the number of the second electrode terminals;
the number of the plurality of electrode terminals of the first capacitor is the same as a number of the plurality of electrode terminals of the second capacitor; and
the first capacitor and the second capacitor are alternately provided in the first direction and the second direction.

6. The capacitor mounting board according to claim 4, wherein, in each of the (M−1)×(N−1)capacitors, the plurality of electrode terminals on the first capacitor main surface are arranged in a staggered pattern.

7. The capacitor mounting board according to claim 6, wherein
in each of the (M−1)×(N−1)capacitors:
a power assignment of an electrode terminal, among the plurality of electrode terminals, that is nearest to the first capacitor side surface is the same as a power assignment of a conductor bump, of the power BGA, that is adjacent to the first capacitor side surface;
a power assignment of an electrode terminal, among the plurality of electrode terminals, that is nearest to the second capacitor side surface is the same as a power assignment of a conductor bump, of the power BGA, that is adjacent to the second capacitor side surface;
a power assignment of an electrode terminal, among the plurality of electrode terminals, that is nearest to the third capacitor side surface is the same as a power assignment of a conductor bump, of the power BGA, that is adjacent to the third capacitor side surface; and
a power assignment of an electrode terminal, among the plurality of electrode terminals, that is nearest to the fourth capacitor side surface is the same as a power assignment of a conductor bump, of the power BGA, that is adjacent to the fourth capacitor side surface.

8. The capacitor mounting board according to claim 5, wherein
in each of the (M−1)×(N−1)capacitors:
an electrode terminal, among the plurality of electrode terminals, that is nearest to the first capacitor side surface is spaced away by a predetermined distance from a conductor bump, of the power BGA, that is adjacent to the first capacitor side surface;
an electrode terminal, among the plurality of electrode terminals, that is nearest to the second capacitor side surface is spaced away by a predetermined distance from a conductor bump, of the power BGA, that is adjacent to the second capacitor side surface;
an electrode terminal, among the plurality of electrode terminals, that is nearest to the third capacitor side surface is spaced away by a predetermined distance from a conductor bump, of the power BGA, that is adjacent to the third capacitor side surface; and
an electrode terminal, among the plurality of electrode terminals, that is nearest to the fourth capacitor side surface is spaced away by a predetermined distance from a conductor bump, of the power BGA, that is adjacent to the fourth capacitor side surface.

9. The capacitor mounting board according to claim 4, wherein
the substrate includes a core layer and two buildup layers respectively provided on the first substrate main surface side and the second substrate main surface side of the core layer; and
each of the two buildup layers includes two or more pairs of wiring layers each including a first-potential wiring layer and a second-potential wiring layer.

10. The capacitor mounting board according to claim 9, wherein
the buildup layer on the second substrate main surface side of the core layer includes:
a plurality of first-potential conductor vias connecting the first-potential wiring layers in the two or more pairs of wiring layers and each of the first-potential lands among the (M×N) power lands; and
a plurality of second-potential conductor vias connecting the second-potential wiring layers in the two or more pairs of wiring layers and each of the second-potential lands among the (M×N) power lands;
the plurality of first-potential conductor vias include conductor vias that are stacked; and
the plurality of second-potential conductor vias include conductor vias that are stacked.

11. The capacitor mounting board according to claim 10, wherein
(M−1)×(N−1)sets of capacitor lands for the plurality of electrode terminals of the (M−1)×(N−1)capacitors are on the second substrate main surface of the substrate;
each set of the (M−1)×(N−1)sets of capacitor lands includes a first-potential capacitor land and a second-potential capacitor land;
the buildup layer on the second substrate main surface side of the core layer includes:
a plurality of first-potential conductor vias connecting the first-potential wiring layer in a pair of wiring layers, among the two or more pairs of wiring layers, that is nearest to the core layer and the first-potential capacitor land in each set of the (M−1)×(N−1)sets of capacitor lands; and
a plurality of second-potential conductor vias connecting the second-potential wiring layer in a pair of wiring layers, among the two or more pairs of wiring layers, that is nearest to the core layer and each of the second-potential capacitor lands in each set of the (M−1)×(N−1)sets of capacitor lands;
the plurality of first-potential conductor vias connected to the first-potential capacitor land include conductor vias that are stacked; and
the plurality of second-potential conductor vias connected to the second-potential capacitor land include conductor vias that are stacked.

12. The capacitor mounting board according to claim 9, wherein
the substrate includes, in the second substrate main surface, (M−1)×(N−1)recesses each of which is provided in a region surrounded by (2×2) power lands, among the (M×N) power lands, that are adjacent to each other in the first direction and the second direction; and
the (M−1)×(N−1)capacitors are respectively embedded in the (M−1)×(N−1)recesses.

13. The capacitor mounting board according to claim 12, wherein, in the buildup layer on the second substrate main surface side, each of the (M−1)×(N−1)recesses extends to some of the plurality of pairs of the first-potential wiring layers and the second-potential wiring layers and does not extend to at least one pair among the plurality of pairs of the first-potential wiring layers and the second-potential wiring layers.

14. A capacitor mounting board comprising:
a substrate including a first substrate main surface on which an integrated circuit (IC) is to be mounted and a second substrate main surface on which a power ball grid array (BGA) to connect with a motherboard is provided;
(M×N) power lands for the power BGA on the second substrate main surface of the substrate two-dimensionally in a first direction and a second direction that intersect each other, where M and N are integers greater than or equal to 2; and
(M−1)×(N−1)capacitors, as seen from the second substrate main surface of the substrate, each in a region surrounded by (2×2) power lands, among the (M×N) power lands, that are adjacent to each other in the first direction and the second direction; wherein
the substrate includes a core layer and two buildup layers respectively provided on the first substrate main surface side and the second substrate main surface side of the core layer and each of which includes a power wiring layer;
each of the (M−1)×(N−1)capacitors:
is embedded in the core layer of the substrate;
includes a first capacitor main surface facing the buildup layer on the first substrate main surface side of the substrate, a second capacitor main surface facing away from the first capacitor main surface, a first capacitor side surface and a third capacitor side surface facing away from each other, and a second capacitor side surface and a fourth capacitor side surface facing away from each other;
includes a plurality of electrode terminals on at least the first capacitor main surface and connected to the power wiring layer of the buildup layer on the first substrate main surface side of the substrate;
has a rectangular or substantially rectangular shape at the first capacitor main surface and the second capacitor main surface; and
is arranged such that an edge of the first capacitor main surface on the first capacitor side surface side and an edge of the first capacitor main surface on the third capacitor side surface side are inclined at about 45±5 degrees with respect to a straight line extending in the first direction on the second substrate main surface of the substrate.

15. The capacitor mounting board according to claim 14, wherein
the (M×N) power lands are arranged at regular intervals on the second substrate main surface of the substrate two-dimensionally in the first direction and the second direction; and
each of the (M−1)×(N−1)capacitors:
has a square or substantially square shape at the first capacitor main surface and the second capacitor main surface;
is arranged such that the edge of the first capacitor main surface on the first capacitor side surface side and the edge of the first capacitor main surface on the third capacitor side surface side are inclined at about 45 degrees with respect to the straight line extending in the first direction on the second substrate main surface of the substrate; and
is arranged such that a center of the first capacitor main surface is positioned at a center of the region surrounded by the (2×2) power lands that are adjacent to each other.

16. The capacitor mounting board according to claim 14, wherein
the (M×N) power lands include first-potential lands and second-potential lands alternately arranged in the first direction and the second direction;
a number of the plurality of electrode terminals on the first capacitor main surface of each of the (M−1)×(N−1) capacitors is greater than or equal to 4; and
the plurality of electrode terminals include first electrode terminals for a first potential and second electrode terminals for a second potential.

17. The capacitor mounting board according to claim 16, wherein
the (M−1)×(N−1)capacitors include a first capacitor in which a number of the first electrode terminals is greater than a number of the second electrode terminals and a second capacitor in which the number of the first electrode terminals is less than the number of the second electrode terminals;
the number of the plurality of electrode terminals of the first capacitor is the same as the number of the plurality of electrode terminals of the second capacitor; and
the first capacitor and the second capacitor are alternately arranged in the first direction and the second direction.

18. The capacitor mounting board according to claim 16, wherein each of the two buildup layers includes, as the power wiring layer, two or more pairs of wiring layers each including a first-potential wiring layer and a second-potential wiring layer.

19. The capacitor mounting board according to claim 18, wherein
the buildup layer on the second substrate main surface side of the core layer includes:
a plurality of first-potential conductor vias connecting the first-potential wiring layers in the two or more pairs of wiring layers and each of the first-potential lands among the (M×N) power lands; and
a plurality of second-potential conductor vias connecting the second-potential wiring layers in the two or more pairs of wiring layers and each of the second-potential lands among the (M×N) power lands;
the plurality of first-potential conductor vias include conductor vias that are stacked; and
the plurality of second-potential conductor vias include conductor vias that are stacked.

20. The capacitor mounting board according to claim 18, wherein
the core layer includes:
a plurality of first-potential one-side core conductor vias extending from the first electrode terminals on the first capacitor main surface of each of the (M−1)×(N−1)capacitors to the buildup layer on the first substrate main surface side of the core layer; and
a plurality of second-potential one-side core conductor vias extending from the second electrode terminals on the first capacitor main surface of each of the (M−1)×(N−1) capacitors to the buildup layer on the first substrate main surface side of the core layer; and
the buildup layer on the first substrate main surface side of the core layer includes:
a plurality of first-potential capacitor conductor vias connecting the first-potential wiring layers in the two or more pairs of wiring layers and each of the plurality of first-potential one-side core conductor vias; and
a plurality of second potential capacitor conductor vias connecting the second-potential wiring layers in the two or more pairs of wiring layers and each of the plurality of second-potential one-side core conductor vias.

21. The capacitor mounting board according to claim 20, wherein
the core layer further includes:
a plurality of first-potential the-other-side core conductor vias extending from the first electrode terminals on the second capacitor main surface of each of the (M−1)×(N−1) capacitors to the buildup layer on the second substrate main surface side of the core layer; and
a plurality of second-potential the-other-side core conductor vias extending from the second electrode terminals on the second capacitor main surface of each of the (M−1)×(N−1) capacitors to the buildup layer on the second substrate main surface side of the core layer;
the buildup layer on the second substrate main surface side of the core layer includes:
a plurality of first-potential capacitor conductor vias connecting the first-potential wiring layer in a pair of wiring layers, among the two or more pairs of wiring layers, that is nearest to the second substrate main surface and each of the plurality of first-potential the-other-side core conductor vias; and
a plurality of second-potential capacitor conductor vias connecting the second-potential wiring layer in a pair of wiring layers, among the two or more pairs of wiring layers, that is nearest to the second substrate main surface and each of the plurality of second-potential the-other-side core conductor vias;
the plurality of first-potential capacitor conductor vias in the buildup layer on the second substrate main surface side of the core layer include conductor vias that are stacked; and
the plurality of second-potential capacitor conductor vias in the buildup layer on the second substrate main surface side of the core layer include conductor vias that are stacked.
